(19) United States
(12) Patent Application Publication
(10) Pub. No.: US 2016/0027530 A1
(43) Pub. Date: Jan. 28, 2016

(54) SEMICONDUCTOR MEMORY APPARATUS

(71) Applicant: SK hynix Inc., Icheon-si (KR)

(72) Inventor: Sung Ho KIM, Icheon-si (KR)

(21) Appl. No.: 14/526,733

(22) Filed: Oct. 29, 2014

(30) Foreign Application Priority Data
Jul. 25, 2014 (KR) 10-2014-0094862

(51) Int. Cl. G11C 29/38; G11C 29/36

(52) U.S. Cl. CPC G11C 29/38; G11C 29/36

(57) ABSTRACT

A semiconductor memory apparatus may include a first data storage region configured to output a first data, a second data storage region configured to output a second data, a third data storage region configured to output a third data, and a fourth data storage region configured to output a fourth data. The apparatus may include a first comparison block configured to compare the first data with the second data, and generate a first comparison signal. The apparatus may include a second comparison block configured to compare the second data with the third data, and generate a second comparison signal. The apparatus may include a third comparison block configured to compare the third data with the fourth data, and generate a third comparison signal. The apparatus may include a signal combination block configured to output a result signal in response to the first to third comparison signals.

### CROSS-REFERENCES TO RELATED APPLICATION

The present application claims priority under 35 U.S.C. §119(a) to Korean application number 10-2014-0094862, filed on Jul. 25, 2014, in the Korean Intellectual Property Office, which is incorporated herein by reference in its entirety.

### BACKGROUND

1. Technical Field

Various embodiments generally relate to a semiconductor integrated circuit, and more particularly, to a semiconductor memory apparatus.

2. Related Art

A semiconductor memory apparatus is configured to store data. The semiconductor memory apparatus is also configured to output the stored data.

A semiconductor memory apparatus may test whether the data has been normally stored. Additionally, the semiconductor memory apparatus may test whether the stored data can be outputted normally, without any errors.

Some tests require that the same data is to be stored in all of the data storage regions of a semiconductor memory apparatus and that all of the data stored in the respective data storage regions be outputted as well. These tests are used for determining whether all of the data that is outputted by the semiconductor memory apparatus is the same data that was stored by the semiconductor memory apparatus. These tests are performed by the semiconductor memory apparatus on its self. In fact, a test circuit for performing such a test is included in the semiconductor memory apparatus.

### SUMMARY

In an embodiment, a semiconductor memory apparatus may include a first data storage region configured to output a first data, a second data storage region configured to output a second data, a third data storage region configured to output a third data, and a fourth data storage region configured to output a fourth data. The semiconductor memory apparatus may include a first comparison block configured to compare the first data with the second data, and generate a first comparison signal. The semiconductor memory apparatus may include a second comparison block configured to compare the second data with the third data, and generate a second comparison signal. The semiconductor memory apparatus may include a third comparison block configured to compare the third data with the fourth data, and generate a third comparison signal. The semiconductor memory apparatus may include a signal combination block configured to output a result signal in response to the first to third comparison signals.

In an embodiment, a semiconductor memory apparatus may include a plurality of data storage regions, and a plurality of comparison blocks configured to compare respective data outputted from the plurality of data storage regions such that one or more data are compared with other data at least a multitude of times. The semiconductor memory apparatus may include a signal combination block configured to compare outputs of the plurality of comparison blocks.

### BRIEF DESCRIPTION OF THE DRAWINGS

FIG. 1 is a configuration diagram illustrating a to representation of an example of a semiconductor memory apparatus in accordance with an embodiment.

FIG. 2 is a configuration diagram illustrating a representation of an example of a semiconductor memory apparatus in accordance with an embodiment.

FIG. 3 is a configuration diagram illustrating a representation of an example of the first comparison block illustrated in FIG. 2.

FIG. 4 is a configuration diagram illustrating a representation of an example of the signal combination block illustrated in FIG. 2.

FIG. 5 illustrates a block diagram of an example of a representation of a system employing the semiconductor memory apparatus in accordance with the embodiments discussed above with relation to FIGS. 1-4.

### DETAILED DESCRIPTION

Hereinafter, a semiconductor memory apparatus will be described below with reference to the accompanying drawings through various examples of embodiments.

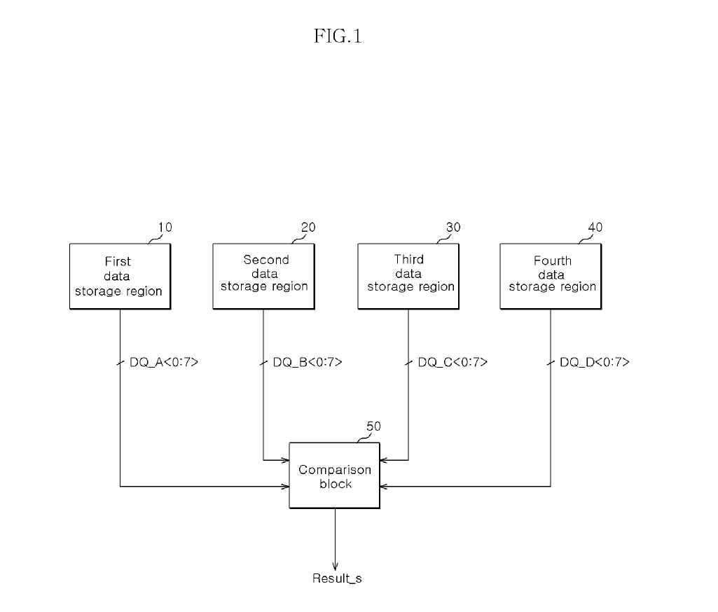

Referring to FIG. 1, a semiconductor memory apparatus in accordance with an embodiment may include first to fourth data storage regions 10, 20, 30 and 40, and a comparison block 50.

The first data storage region 10 may be configured to store data. The first data storage region 10 may be configured to output the stored data as first data DQ_A<0:7>.

The second data storage region 20 may be configured to store data. The second data storage region 20 may be configured to output the stored data as second data DQ_B<0:7>.

The third data storage region 30 may be configured to store data. The third data storage region 30 may be configured to output the stored data as third data DQ_C<0:7>.

The fourth data storage region 40 may be configured to store data. The fourth data storage region 40 may be configured to output the stored data as fourth data DQ_D<0:7>.

The comparison block 50 may determine whether all of the first to fourth data DQ_A<0:7>, DQ_B<0:7>, DQ_C<0:7> and DQ_D<0:7> are the same data. After making a determination the comparison block 50 may output a determination result as a result signal Result_s. For example, the comparison block 50 may enable the result signal Result_s when the first to fourth data DQ_A<0:7>, DQ_B<0:7>, DQ_C<0:7> and DQ_D<0:7> are all the same. For example, the comparison block 50 may disable the result signal Result_s when the first to fourth data DQ_A<0:7>, DQ_B<0:7>, DQ_C<0:7> and DQ_D<0:7> are not all the same.

In an embodiment, the semiconductor memory apparatus may operate in such a manner that the same data are stored in all of the first to fourth data storage regions 10, 20, 30 and 40 and the data stored in the respective data storage regions 10, 20, 30 and 40 are outputted as the first to fourth data DQ_A<0:7>, DQ_B<0:7>, DQ_C<0:7> and DQ_D<0:7>. The comparison block 50 may enable the result signal Result_s when the first to fourth data DQ_A<0:7>, DQ_B<0:7>, DQ_C<0:7> and DQ_D<0:7> are all the same. Conversely, the comparison block 50 may disable the result signal Result_s when the first to fourth data DQ_A<0:7>, DQ_B<0:7>, DQ_C<0:7> and DQ_D<0:7> are not all the same.

The semiconductor memory apparatus may perform a test for determining whether the respective data storage regions 10, 20, 30 and 40 are normally storing the data, by using or determining whether the result signal Result_s is enabled or not.

Data input/output lines for transferring the first to fourth data DQ_A<0:7>, DQ_B<0:7>, DQ_C<0:7> and DQ_D<0:7> from the first to fourth data storage regions 10, 20, 30 and 40 to the comparison block 50 should be electrically coupled. Each of the first to fourth data DQ_A<0:7>, DQ_B<0:7>, DQ_C<0:7> and DQ_D<0:7> is configured by 8 bits, and each bit is transferred to the comparison block 50 through one data input/output line. Therefore, a total of 32 data input/output lines should be electrically coupled from the four data storage regions 10, 20, 30 and 40 to the one comparison block 50.

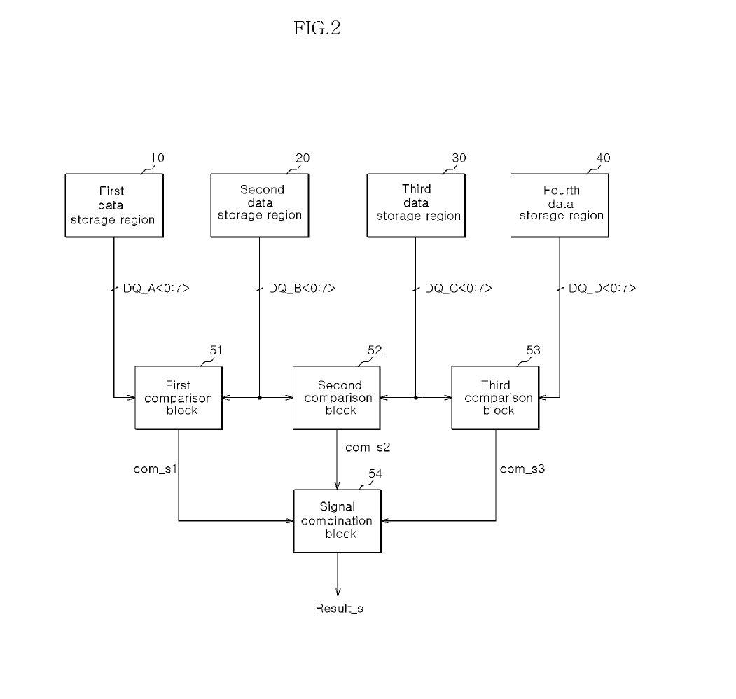

To perhaps prevent the deterioration of the areal efficiency of the semiconductor memory apparatus due to the large number of metal data input/output lines electrically coupled to one circuit a semiconductor memory apparatus utilizing the features related with the embodiments discussed below with regards to FIG. 2 may be to implemented.

Referring to FIG. 2, a semiconductor memory apparatus in accordance with an embodiment may include first to fourth data storage regions 10, 20, 30 and 40, first to third comparison blocks 51, 52 and 53, and a signal combination block 54.

The first data storage region 10 may be configured to store data. The first data storage region 10 may be configured to output the stored data as first data DQ_A<0:7>.

The second data storage region 20 may be configured to store data. The second data storage region 20 may be configured to output the stored data as second data DQ_B<0:7>.

The third data storage region 30 may be configured to store data. The third data storage region 30 may be configured to output the stored data as third data DQ_C<0:7>.

The fourth data storage region 40 may be configured to store data. The fourth data storage region 40 may be configured to output the stored data as fourth data DQ_D<0:7>.

The first comparison block 51 may compare the first data DQ_A<0:7> and the second data DQ_B<0:7>, and may generate a first comparison signal com_s1. For example, the first comparison block 51 may enable the first comparison signal com_s1 when the first data DQ_A<0:7> and the second data DQ_B<0:7> are all the same. For example, the first comparison block 51 may disable the first comparison signal com_s1 when the first data DQ_A<0:7> and the second data DQ_B<0:7> are not all the same.

The second comparison block 52 may compare the second data DQ_B<0:7> and the third data DQ_C<0:7>, and may generate a second comparison signal com_s2. For example, the second comparison block 52 may enable the second comparison signal com_s2 when the second data DQ_B<0:7> and the third data DQ_C<0:7> are all the same. For example, the second comparison block 52 may disable the second comparison signal com_s2 when the second data DQ_B<0:7> and the third data DQ_C<0:7> are not all the same.

The third comparison block 53 may compare the third data DQ_C<0:7> and the fourth data DQ_D<0:7>, and may generate a third comparison signal com_s3. For example, the third comparison block 53 may enable the third comparison signal com_s3 when the third data DQ_C<0:7> and the fourth data DQ_D<0:7> are all the same. For example, the third comparison block 53 may disable the third comparison signal com_s3 when the third data DQ_C<0:7> and the fourth data DQ_D<0:7> are not all the same.

The signal combination block 54 may generate a result signal Result_s in response to the first to third comparison signals com_s1, com_s2 and com_s3. For example, the signal combination block 54 disables the result signal Result_s when even one of the first to third comparison signals com_s1, com_s2 and com_s3 are disabled. For example, the signal combination block 54 enables the result signal Result_s only when the first to third comparison signals com_s1, com_s2 and com_s3 are all enabled.

The configurations of the respective first to third comparison blocks 51, 52 and 53 are substantially the same except that the signals inputted thereto and the signals outputted therefrom are different. Therefore, the description of the configuration of the first comparison block 51 will replace the descriptions of the is configurations of the other comparison blocks 52 and 53.

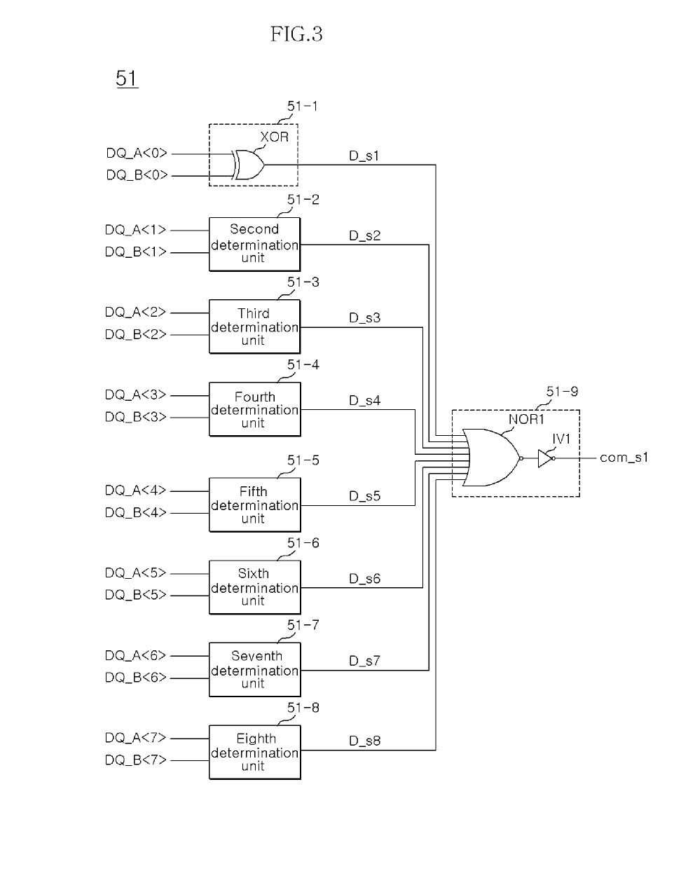

Referring to FIG. 3, the first comparison block 51 may include first to eighth determination units 51-1, 51-2, 51-3, 51-4, 51-5, 51-6, 51-7 and 51-8, and a comparison signal generation unit 51-9.

The first determination unit 51-1 may compare the first bit DQ_A<0> of the first data DQ_A<0:7> and the first bit DQ_B<0> of the second data DQ_B<0:7>. The first determination unit 51-1 may generate a first determination signal D_s1. For example, the first determination unit 51-1 may enable the first determination signal D_s1 to a low level when the first bit DQ_A<0> of the first data DQ_A<0:7> and the first bit DQ_B<0> of the second data DQ_B<0:7> are the same with each other. For example, the first determination unit 51-1 may disable the first determination signal D_s1 to a high level when the first bit DQ_A<0> of the first data DQ_A<0:7> and the first bit DQ_B<0> of the second data DQ_B<0:7> are different from each other.

For example, the first determination unit 51-1 may include an exclusive OR gate XOR. The exclusive OR gate XOR may be inputted with the first bit DQ_A<0> of the first data DQ_A<0:7> and the first bit DQ_B<0> of the second data DQ_B<0:7>, and may output the first determination signal D_s1.

The second determination unit 51-2 may compare the second bit DQ_A<1> of the first data DQ_A<0:7> and the second bit DQ_B<1> of the second data DQ_B<0:7>. The second determination unit 51-2 may generate a second determination signal D_s2. For example, the second determination unit 51-2 may enable the second determination signal D_s2 to a low level when the second bit DQ_A<1> of the first data DQ_A<0:7> and the second bit DQ_B<1> of the second data DQ_B<0:7> are the same with each other. For example, the second determination unit 51-2 may disable the second determination signal D_s2 to a high level when the second bit DQ_A<1> of the first data DQ_A<0:7> and the second bit DQ_B<1> of the second data DQ_B<0:7> are different from each other. For example, the second determination unit 51-2 may be configured by an exclusive OR gate, in the same manner as the first determination unit 51-1.

The third determination unit 51-3 may compare the third bit DQ_A<2> of the first data DQ_A<0:7> and the third bit DQ_B<2> of the second data DQ_B<0:7>. The third determination unit 51-3 may generate a third determination signal D_s3. For example, the third determination unit 51-3 may enable the third determination signal D_s3 to a low level when the third bit DQ_A<2> of the first data DQ_A<0:7> and the third bit DQ_B<2> of the second data DQ_B<0:7> are the same with each other. For example, the third determination unit 51-3 may disable the third determination signal D_s3 to a high level when the third bit DQ_A<2> of the first data DQ_A<0:7> and the third bit DQ_B<2> of the second data DQ_B<0:7> are different from each other. For example, the third determination unit 51-3 may be configured by an exclusive OR gate, in the same manner as the first determination unit 51-1.

The fourth determination unit 51-4 may compare the fourth bit DQ_A<3> of the first data DQ_A<0:7> and the fourth bit DQ_B<3> of the second data DQ_B<0:7>. The fourth determination unit 51-4 may generate a fourth determination signal D_s4. For example, the fourth determination unit 51-4 may enable the fourth determination signal D_s4 to a low level when the fourth bit DQ_A<3> of the first data DQ_A<0:7> and the fourth bit DQ_B<3> of the second data DQ_B<0:7> are the same with each other. For example, the fourth determination unit 51-4 may disable the fourth determination signal D_s4 to a high level when the fourth bit DQ_A<3> of the first data DQ_A<0:7> and the fourth bit DQ_B<3> of the second data DQ_B<0:7> are different from each other. For example, the fourth determination unit 51-4 may be configured by an exclusive OR gate, in the same manner as the first determination unit 51-1.

The fifth determination unit 51-5 may compare the fifth bit DQ_A<4> of the first data DQ_A<0:7> and the fifth bit DQ_B<4> of the second data DQ_B<0:7>. The fifth determination unit 51-5 may generate a fifth determination signal D_s5. For example, the fifth determination unit 51-5 may enable the fifth determination signal D_s5 to a low level when the fifth bit DQ_A<4> of the first data DQ_A<0:7> and the fifth bit DQ_B<4> of the second data DQ_B<0:7> are the same with each other. For example, the fifth determination unit 51-5 may disable the fifth determination signal D_s5 to a high level when the fifth bit DQ_A<4> of the first data DQ_A<0:7> and the fifth bit DQ_B<4> of the second data DQ_B<0:7> are different from each other. For example, the fifth determination unit 51-5 may be configured by an exclusive OR gate, in the same manner as the first determination unit 51-1.

The sixth determination unit 51-6 may compare the sixth bit DQ_A<5> of the first data DQ_A<0:7> and the sixth bit DQ_B<5> of the second data DQ_B<0:7>. The sixth determination unit 51-6 may generate a sixth determination signal D_s6. For example, the sixth determination unit 51-6 may enable the sixth determination signal D_s6 to a low level when the sixth bit DQ_A<5> of the first data DQ_A<0:7> and the sixth bit DQ_B<5> of the second data DQ_B<0:7> are the same with each other. For example, the sixth determination unit 51-6 may disable the sixth determination signal D_s6 to a high level when the sixth bit DQ_A<5> of the first data DQ_A<0:7> and the sixth bit DQ_B<5> of the second data DQ_B<0:7> are different from each other. For example, the sixth determination unit 51-6 may be configured by an exclusive OR gate, in the same manner as the first determination unit 51-1.

The seventh determination unit 51-7 may compare the seventh bit DQ_A<6> of the first data DQ_A<0:7> and the seventh bit DQ_B<6> of the second data DQ_B<0:7>. The seventh determination unit 51-7 may generate a seventh determination signal D_s7. For example, the seventh determination unit 51-7 may enable the seventh determination signal D_s7 to a low level when the seventh bit DQ_A<6> of the first data DQ_A<0:7> and the seventh bit DQ_B<6> of the second data DQ_B<0:7> are the same with each other. For example, the seventh determination unit 51-7 may disable the seventh determination signal D_s7 to a high level when the seventh bit DQ_A<6> of the first data DQ_A<0:7> and the seventh bit DQ_B<6> of the second data DQ_B<0:7> are different from each other. For example, the seventh determination unit 51-7 may be configured by an exclusive OR gate, in the same manner as the first determination unit 51-1.

The eighth determination unit 51-8 may compare the eighth bit DQ_A<7> of the first data DQ_A<0:7> and the eighth bit DQ_B<7> of the second data DQ_B<0:7>. The eighth determination unit 51-8 may generate an eighth determination signal D_s8. For example, the eighth determination unit 51-8 may enable the eighth determination signal D_s8 to a low level when the eighth bit DQ_A<7> of the first data DQ_A<0:7> and the eighth bit DQ_B<7> of the second data DQ_B<0:7> are the same with each other. For example, the eighth determination unit 51-8 may disable the eighth determination signal D_s8 to a high level when the eighth bit DQ_A<7> of the first data DQ_A<0:7> and the eighth bit DQ_B<7> of the second data DQ_B<0:7> are different from each other. For example, the eighth determination unit 51-8 may be configured by an exclusive OR gate, in the same manner as the first determination unit 51-1.

The comparison signal generation unit 51-9 may disable the first comparison signal com_s1 when even any one of the first to eighth determination signals D_s1 to D_s8 are disabled. The comparison signal generation unit 51-9 may enable the first comparison signal com_s1 when all of the first to eighth determination signals D_s1 to D_s8 are all enabled.

For example, the comparison signal generation unit 51-9 may include a first NOR gate NOR1 and a first inverter IV1. The first NOR gate NOR1 may be inputted with the first to eighth determination signals D_s1 to D_s8. The first inverter IV1 may be inputted with the output signal of the first NOR gate NOR1, and may output the first comparison signal com_s1.

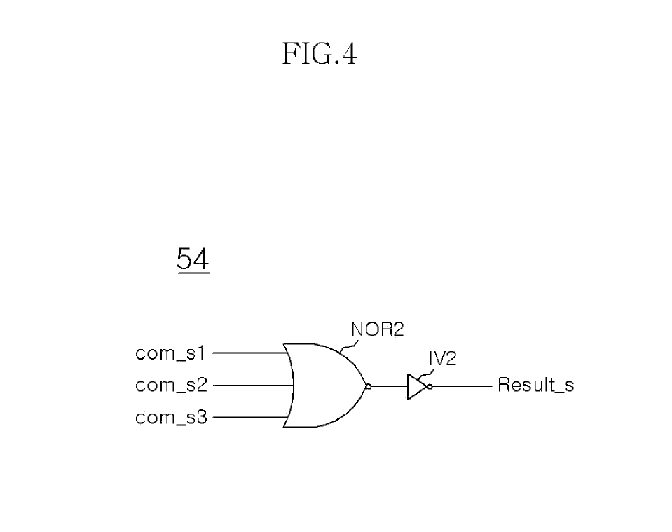

Referring to FIG. 4, the signal combination block 54 may include, for example, a second NOR gate NOR2, and a second inverter IV2. The second NOR gate NOR2 may be inputted with the first to third comparison signals com_s1, com_s2 and com_s3. The second inverter 1V2 may be inputted with the output signal of the second NOR gate NOR2, and may output the result signal Result_s.

For example, the signal combination block 54 may output the result signal Result_s enabled to a low level when the first to third comparison signals com_s1, com_s2 and com_s3 are all enabled to low levels. For example, the signal combination block 54 may to disable the result signal Result_s to a high level when even any one of the first to third comparison signals com_s1, com_s2 and com_s3 are disabled to a high level.

Operations of the semiconductor memory apparatus in accordance with the embodiments, configured as mentioned above, will be described below.

After all of the same data is stored in the first data storage region 10, the second data storage region 20, the third data storage region 30 and the fourth data storage region 40, the stored data is then outputted. All of the data outputted from the first data storage region 10 is first data DQ_A<0:7>, all of the data outputted from the second data storage region 20 is second data DQ_B<0:7>, all of the data outputted from the third data storage region 30 is third data DQ_C<0:7>, and all of the data outputted from the fourth data storage region 40 is fourth data DQ_D<0:7>.

The first comparison block 51 may enable the first comparison signal com_s1 to the low level when the first data DQ_A<0:7> and the second data DQ_B<0:7> are all the same. The first comparison block 51 may disable the first comparison signal com_s1 to the high level when the first data DQ_A<0:7> and the second data DQ_B<0:7> are not all the same.

The second comparison block 52 may enable the second comparison signal com_s2 to the low level when the second data DQ_B<0:7> and the third data DQ_C<0:7> are all the same. The second comparison block 52 may disable the second comparison signal com_s2 to the high level when the second data DQ_B<0:7> and the third data DQ_C<0:7> are not all the same.

The third comparison block 53 may enable the third comparison signal com_s3 to the low level when the third data DQ_C<0:7> and the fourth data DQ_D<0:7> are all the same. The third comparison block 53 may disable the third comparison signal com_s3 to the high level when the third data DQ_C<0:7> and the fourth data DQ_D<0:7> are not all the same.

The signal combination block 54 may output the result signal Result_s enabled to the low level when the first to third comparison signals com_s1, com_s2 and com_s3 are all enabled to the low levels. The signal combination block 54 may disable the result signal Result_s to the high level when even any one of the first to third comparison signals com_s1, com_s2 and com_s3 are disabled to the high level.

The operations of the semiconductor memory apparatus in accordance with the embodiments may be summarized as in the following table wherein the letter L represents the same and the letter H represents not the same.

| Result of | Result of | Result of | |
|---|---|---|---|
| comparing | comparing | Comparing | Result |
| DQ_A<0:7> and | DQ_B<0:7> and | DQ_C<0:7> and | signal |
| DQ_B<0:7> | DQ_C<0:7> | DQ_D<0:7> | (Result_s) |
| L | L | L | L (enable) |
| L | L | H | H (disable) |
| L | H | L | H (disable) |
| L | H | H | H (disable) |
| H | L | L | H (disable) |
| H | L | H | H (disable) |
| H | H | L | H (disable) |
| H | H | H | H (disable) |

Referring to the table, the semiconductor memory apparatus in accordance with the embodiments may know whether a plurality of data storage regions normally store data, by enabling a result signal when the data outputted from the plurality of data storage regions are all the same and disabling the result signal when the data outputted from the plurality of data storage regions are not all the to same.

The semiconductor memory apparatus in accordance with the embodiments may include a plurality of comparison blocks in such a manner that the respective data outputted from the plurality of data storage regions are compared with one another and at least one data (for example, the second and third data DQ_B<0:7> and DQ_C<0:7>) are compared with other data at least a multitude of times. In detail, the plurality of comparison blocks are configured to compare at least one data among the data outputted from the plurality of data storage regions with at least two respective data outputted from different data storage regions. Referring to FIG. 2, the second data DQ_B<0:7> are compared with the first data DQ_A<0:7> and are compared with the third data DQ_C<0:7>, and the third data DQ_C<0:7> are compared with the second data DQ_B<0:7> and are compared with the fourth data DQ_D<0:7>. In the semiconductor memory apparatus in accordance with the embodiments illustrated in FIG. 2, unlike the semiconductor memory apparatus illustrated in FIG. 1, since the data outputted from the to respective data storage regions are compared in a distributed manner, that is, the data outputted from two data storage regions are compared with each other, data input/output lines for transferring the data outputted from the respective data storage regions may be disposed in a distributed manner.

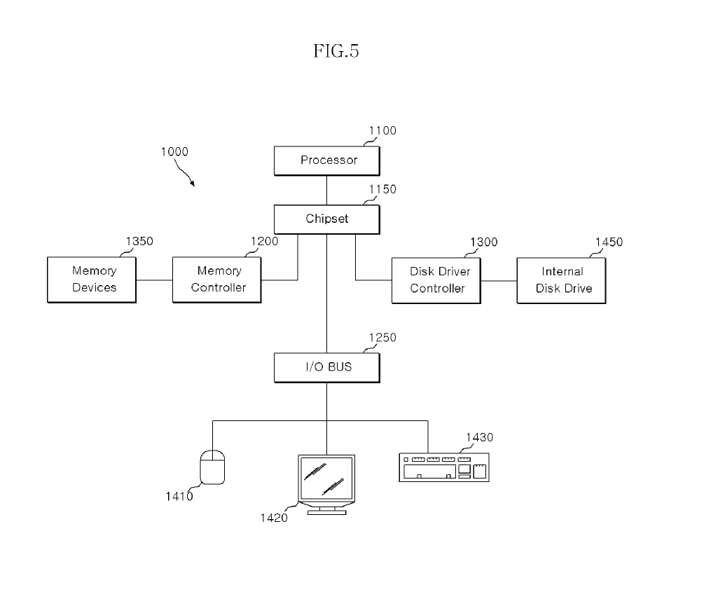

The semiconductor memory apparatuses discussed above (see FIGS. 1-4) are particular useful in the design of memory devices, processors, and computer systems. For example, referring to FIG. 5, a block diagram of a system employing the semiconductor memory apparatuses in accordance with the embodiments are illustrated and generally designated by a reference numeral 1000. The system 1000 may include one or more processors or central processing units (“CPUs”) 1100. The CPU 1100 may be used individually or in combination with other CPUs. While the CPU 1100 will be referred to primarily in the singular, it will be understood by those skilled in the art that a system with any number of physical or logical CPUs may be implemented.

A chipset 1150 may be operably coupled to the CPU 1100. The chipset 1150 is a communication pathway for signals between the CPU 1100 and other components of the system 1000, which may include a memory controller 1200, an input/output (“I/O”) bus 1250, and a disk drive controller 1300. Depending on the configuration of the system, any one of a number of different signals may be transmitted through the chipset 1150, and those skilled in the art will appreciate that the routing of the signals throughout the system 1000 can be readily adjusted without changing the underlying nature of the system.

As stated above, the memory controller 1200 may be operably coupled to the chipset 1150. The memory controller 1200 may include at least one semiconductor memory apparatus as is discussed above with reference to FIGS. 1-4. Thus, the memory controller 1200 can receive a request provided from the CPU 1100, through the chipset 1150. In alternate embodiments, the memory controller 1200 may be integrated into the chipset 1150. The memory controller 1200 may be operably coupled to one or more memory devices 1350. In an embodiment, the memory devices 1350 may include the at least one semiconductor memory apparatus as discussed above with relation to FIGS. 1-4, the memory devices 1350 may include a plurality of word lines and a plurality of bit lines for defining a plurality of memory cell. The memory devices 1350 may be any one of a number of industry standard memory types, including but not limited to, single inline memory modules (“SIMMs”) and dual inline memory modules (“DIMMs”). Further, the memory devices 1350 may facilitate the safe removal of the external data storage devices by storing both instructions and data.

The chipset 1150 may also be coupled to the I/O bus 1250. The I/O bus 1250 may serve as a communication pathway for signals from the chipset 1150 to I/O devices 1410, 1420 and 1430. The I/O devices 1410, 1420 and 1430 may include a mouse 1410, a video display 1420, or a keyboard 1430. The I/O bus 1250 may employ any one of a number of communications protocols to communicate with the I/O devices 1410, 1420, and 1430. Further, the I/O bus 1250 may be integrated into the chipset 1150.

The disk drive controller 1450 (i.e., internal disk drive) may also be operably coupled to the chipset 1150. The disk drive controller 1450 may serve as the communication pathway between the chipset 1150 and one or more internal disk drives 1450. The internal disk drive 1450 may facilitate disconnection of the external data storage devices by storing both instructions and data. The disk drive controller 1300 and the internal disk drives 1450 may communicate with each other or with the chipset 1150 using virtually any type of communication protocol, including all of those mentioned above with regard to the I/O bus 1250.

It is important to note that the system 1000 described above in relation to FIG. 5 is merely one example of a system employing the semiconductor memory apparatus as discussed above with relation to FIGS. 1-4. In alternate embodiments, such as cellular phones or digital cameras, the components may differ from the embodiments illustrated in FIG. 5.

While various embodiments have been described above, it will be understood to those skilled in the art that the embodiments described are by way of example only. Accordingly, the semiconductor memory apparatus described herein should not be limited based on the described embodiments.

What is claimed is:

1. A semiconductor memory apparatus comprising:
a first data storage region configured to output a first data;
a second data storage region configured to output a second data;
a third data storage region configured to output a third data;
a fourth data storage region configured to output a fourth data;
a first comparison block configured to compare the first data with the second data, and generate a first comparison signal;
a second comparison block configured to compare the second data with the third data, and generate a second comparison signal;
a third comparison block configured to compare the third data with the fourth data, and generate a third comparison signal; and
a signal combination block configured to output a result signal in response to the first to third comparison signals.

2. The semiconductor memory apparatus according to claim 1, wherein each of the first to third comparison blocks enables the comparison signal when the data inputted thereto are all the same, and disables the comparison signal when the data inputted thereto are not all the same.

3. The semiconductor memory apparatus according to claim 2, wherein the signal combination block enables the result signal when the first to third comparison signals are all enabled, and disables the result signal when even any one of the first to third comparison signals is disabled.

4. A semiconductor memory apparatus comprising:
a plurality of data storage regions;
a plurality of comparison blocks configured to compare respective data outputted from the plurality of data storage regions such that one or more data are compared with other data at least a multitude of times; and
a signal combination block configured to compare outputs of the plurality of comparison blocks.

5. The semiconductor memory apparatus according to claim 4, wherein the signal combination block outputs a result signal in response to the comparison of the outputs received from the plurality of comparison blocks.

6. The semiconductor memory apparatus according to claim 5, wherein the plurality of comparison blocks compare one or more data among the data outputted from the plurality of data storage regions with at least two data outputted from different data storage regions.

7. The semiconductor memory apparatus according to claim 6, wherein the plurality of data storage regions comprise first to fourth data storage regions, the plurality of comparison blocks comprise first to third comparison blocks, the first comparison block compares data outputted from the first data storage region and the second data storage region, the second comparison block compares data outputted from the second data storage region and the third data storage region, and the third comparison block compares data outputted from the third data storage region and the fourth data storage region.

8. The semiconductor memory apparatus according to claim 7, wherein each of the first to third comparison blocks enables a comparison signal when the data inputted thereto are all the same, and disables the comparison signal when the data inputted thereto is are not all the same.

9. The semiconductor memory apparatus according to claim 8, wherein the signal combination block enables the result signal when comparison signals outputted from the first to third respective comparison blocks are all enabled, and disables the result signal when even one of the comparison signals outputted from the first to third respective comparison blocks is disabled.

10. A semiconductor memory apparatus comprising:
a plurality of data storage regions;
a plurality of comparison blocks configured to compare respective data outputted from the plurality of data storage regions such that one or more data are compared with other data at least a multitude of times; and
a signal combination block configured to compare outputs of the plurality of comparison blocks to determine if all of the data is the same.

11. The semiconductor memory apparatus according to claim 10, wherein the signal combination block includes a logic gate for receiving the outputs of the plurality of comparison blocks and outputting a result signal.

12. The semiconductor memory apparatus according to claim 11, wherein the logic gate includes a NOR gate.
